(19) United States
(12) Patent Application Publication
(10) Pub. No.: US 2026/0183661 A1
(43) Pub. Date: Jul. 2, 2026

(54) INFORMATION PROCESSING DEVICE, INFORMATION PROCESSING METHOD, AND PROGRAM

(71) Applicant: Sony Interactive Entertainment Inc., Tokyo (JP)

(72) Inventors: Shogo Sato, Tokyo (JP); Hiroyuki Segawa, Kanagawa (JP); Tetsugo Inada, Tokyo (JP)

(21) Appl. No.: 19/547,503

(22) Filed: Feb. 23, 2026

Related U.S. Application Data
(63) Continuation of application No. PCT/JP2023/031786, filed on Aug. 31, 2023.

(51) Int. Cl. A63F 13/52; A63F 13/5375; G06F 30/27

(52) U.S. Cl. CPC A63F 13/52; A63F 13/5375; G06F 30/27

(57) ABSTRACT

An information processing device that sequentially acquires, with regard to target content having details that change over time, screen data related to details on a screen of the target content while the target content is being output; sequentially acquires model output data corresponding to the screen data related to the details on the screen of the target content using a machine learning model obtained by machine learning a relationship between the screen data and descriptive information that linguistically describes the details of the screen data; and executes predetermined processing based on the acquired model output data

### CROSS-REFERENCE TO RELATED APPLICATIONS

This application is a Continuation of International Application No. PCT/JP2023/031786, having an International Filing Date of Aug. 31, 2023. This disclosure of the prior application is considered part of the disclosure of this application.

### FIELD

The present specification relates to an information processing device, an information processing method, and a program, for generating a moving image.

### BACKGROUND

When a user plays a video game, for example, an information processing device sequentially generates content (moving images and audio) having details that change over time in response to an operational input, behavior, or the like of a user, and presents such content to the user.

### SUMMARY

When presenting the content described above, it is desirable that the information processing device be able to present details that are in line with the scene or situation, such as by advising the user on operations that should be performed or by reacting to the behavior of the user. However, simply presenting details determined based on pre-prepared conditions may result in the presented details becoming monotonous, or it may become necessary to set complex conditions in advance in order to present a variety of details. Thus, it is difficult to present details that are appropriate to each individual user's situation.

The present specification has been conceived in consideration of the above circumstances, and an object thereof is to provide an information processing device, an information processing method, and a program that are capable of presenting guidance, a response, or the like, according to the situation of the user.

An information processing device according to one aspect of the present specification is an information processing device provided with one or more processors, wherein the one or more processors sequentially acquire, with regard to target content having details that change over time, screen data related to details on a screen of the target content while the target content is being output; sequentially acquire model output data corresponding to the screen data related to the details on the screen of the target content using a machine learning model obtained by machine learning a relationship between the screen data and descriptive information that linguistically describes the details of the screen data; and execute predetermined processing based on the acquired model output data.

An information processing method according to one aspect of the present specification is an information processing method for sequentially acquiring, with regard to target content having details that change over time, screen data related to details on a screen of the target content while the target content is being output; sequentially acquiring model output data corresponding to the screen data related to the details on the screen of the target content using a machine learning model obtained by machine learning a relationship between the screen data and descriptive information that linguistically describes the details of the screen data, and executing predetermined processing based on the acquired model output data.

A program according to one aspect of the present specification is a program for causing a computer to execute processing for sequentially acquiring, with regard to target content having details that change over time, screen data related to details on a screen of the target content while the target content is being output; sequentially acquiring model output data corresponding to the screen data related to the details on the screen of the target content using a machine learning model obtained by machine learning a relationship between the screen data and descriptive information that linguistically describes the details of the screen data; and executing predetermined processing based on the acquired model output data. The program may be provided by being stored in a computer-readable non-transitory information storage medium.

### BRIEF DESCRIPTION OF THE DRAWINGS

FIG. 1 is a configurational block diagram illustrating a configuration of the information processing device according to an implementation.

FIG. 2 is a functional block diagram illustrating functions of the information processing device according to an implementation.

FIG. 3 is a diagram for describing one example of a learning process for generating a machine learning model used by the information processing device according to an implementation.

FIG. 4 is a diagram for describing one example of a process in which the information processing device according to an implementation of the present specification presents guidance information.

### DETAILED DESCRIPTION

Hereinafter, implementations of the present specification will be described in detail with reference to the drawings.

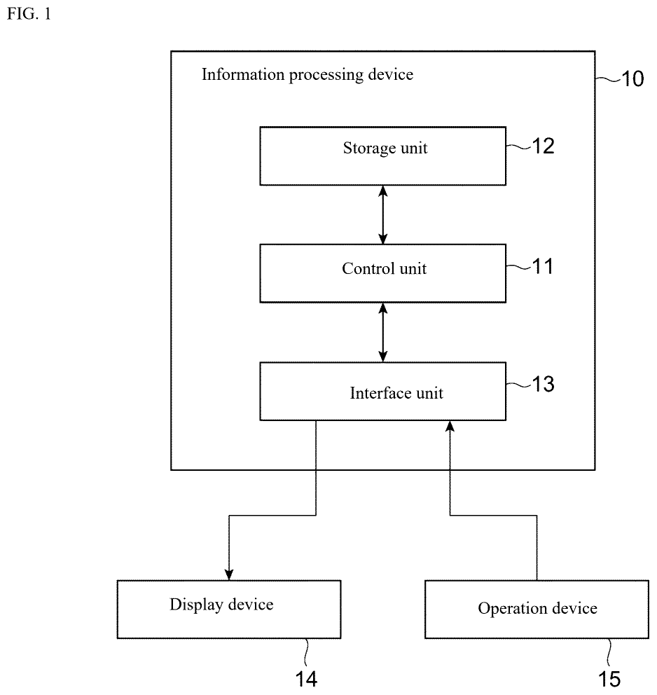

FIG. 1 is configurational block diagram illustrating a configuration of an information processing device 10 according to one implementation of the present specification. The information processing device 10 is a personal computer, a server computer, or the like, and as shown in the drawing, is configured to include a control unit 11, a storage unit 12, and an interface unit 13. The information processing device 10 is also connected to a display device 14 and an operation device 15.

The control unit 11 includes at least one processor such as a CPU, and executes a program stored in the storage unit 12 to execute various types of information processing. Note that specific examples of the processing executed by the control unit 11 in the present implementation will be described later. The storage unit 12 includes at least one memory device such as a RAM, and stores the program executed by the control unit 11 and data processed by the program.

The interface unit 13 is an interface for data communication between the display device 14 and the operation device 15. The information processing device 10 is connected to each of the display device 14 and the operation device 15 via the interface unit 13 by either wired or wireless means. Specifically, the interface unit 13 includes a multimedia interface for transmitting a video signal supplied by the information processing device 10 to the display device 14. The interface unit 13 also includes a data communication interface for receiving a signal indicating the details of an operation performed by the user on the operation device 15.

The display device 14 displays an image corresponding to the video signal supplied from the information processing device 10 on the screen. The operation device 15 is, for example, a keyboard or a mouse, and receives an operational input from the user. The operation device 15 is connected to the information processing device 10 by wired or wireless means, and transmits to the information processing device 10 an operation signal indicating the details of an operational input received from the user.

Although not illustrated in FIG. 1, the information processing device 10 may be connected to various devices, such as a microphone and a camera, that acquire information from the user in real time. The device may also be configured to be capable of connecting and communicating with information processing devices such as terminal devices and server devices used by other users.

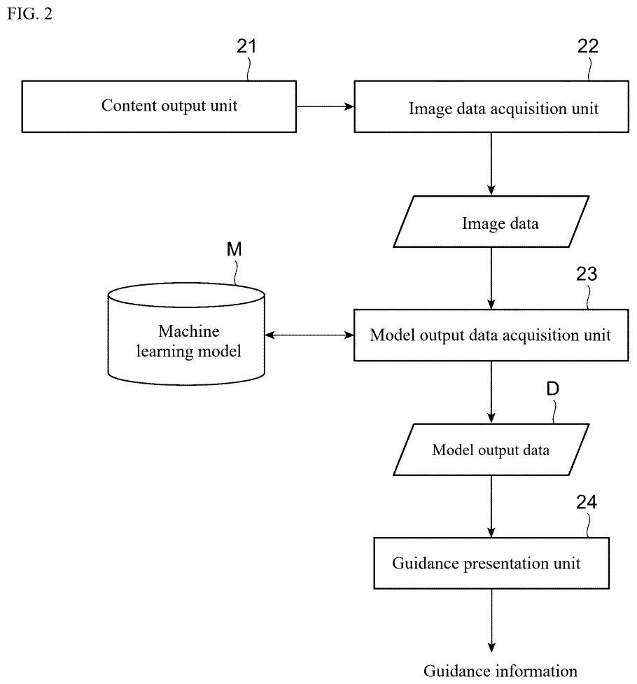

The functions realized by the information processing device 10 will be described below with reference to the functional block diagram of FIG. 2. As illustrated in FIG. 2, the information processing device 10 is functionally configured to include a content output unit 21, a screen data acquisition unit 22, a model output data acquisition unit 23, and a guidance presentation unit 24. These functions are realized by the control unit 11 operating in accordance with one or a plurality of programs stored in the storage unit 12. These programs may be provided in the information processing device 10 via a communication network such as the Internet, or may be provided by being stored in a computer-readable information storage medium such as an optical disk.

The content output unit 21 is realized by executing an application program, and generates and outputs content to be presented to the user. For example, the content output unit 21 is realized by a game program. In this case, the content output unit 21 executes game processing in accordance with the operational input of the user, and renders and outputs a game screen showing the results thereof. Hereinafter, the content output by the content output unit 21 will be referred to as target content C. In the present implementation, the target content C is content having details that change over time, and includes at least a moving image that is presented to the user. In the following description, a user who uses the information processing device 10 to view the target content C in real time will be referred to as a user U.

The target content C presented to the user U by the content output unit 21 may include a moving image rendering the state of a virtual three-dimensional space. In this case, the content output unit 21 determines the appearance of various objects to be placed in the virtual three-dimensional space, and instructs the rendering engine to render a spatial image showing the state of the virtual three-dimensional space. The spatial image rendered in response to this rendering instruction is displayed on the display device 14 as a frame image constituting the target content C.

Note that the program that realizes the content output unit 21 may be a separate program from the programs that realize the screen data acquisition unit 22, the model output data acquisition unit 23, and the guidance presentation unit 24, or may be the same program. As a specific example, the following describes a case wherein the screen data acquisition unit 22, the model output data acquisition unit 23, and the guidance presentation unit 24 are realized by a program independent of the content output unit 21.

The screen data acquisition unit 22 sequentially acquires screen data related to the screen details of the target content C output by the content output unit 21. As a specific example, the screen data may be the frame images of a moving image that are rendered by the content output unit 21 and displayed on the display device 14. Furthermore, the screen data acquired by the screen data acquisition unit 22 may be rendering data output by the content output unit 21 in order to render the state of the virtual three-dimensional space. In this case, the screen data includes information that identifies the appearance, position, orientation, and the like of various objects placed in the virtual space.

The screen data acquisition unit 22 acquires the latest screen data at that time from the content output unit 21, for example, at predetermined time intervals. As a result, the screen data acquisition unit 22 acquires screen data related to the screen details presented to the user U in chronological order in real time.

Furthermore, the screen data acquisition unit 22 may sequentially acquire time-series information indicating the situation of the user U from the content output unit 21. As a specific example, time-series information S may be time-series operation information indicating the details of the operational input performed on the operation device 15 by the user U watching the target content C, such as a game, while the target content C is being output. The time-series operation information includes information that can identify the details of the operation performed by the user U (for example, the button pressed, the direction and amount of operation of a stick-type operating member, and the like) and the timing at which the operation was performed.

Furthermore, the time-series information is not limited to time-series operation information, but may be various types of information related to the situation of the user U while the target content C is being output. For example, the time-series information may include information obtained by recording, in real time, and using various sensors, vital signs (such as heart rate) and actions (such as body movements) of the user U while watching the target content C. The time-series information may also include information such as facial expressions and eye movements of the user U obtained by capturing an image of the user U using a camera. The time-series information may also include voice data obtained by recording details spoken by the user U using a microphone. Furthermore, the screen data acquisition unit 22 may acquire information obtained by analyzing the information recorded in real time as time-series information. For example, by analyzing images obtained by capturing images of the user U and information on body movements of the user U, and the like, the screen data acquisition unit 22 may acquire, as time-series information, information indicating that the user U left his/her seat at a predetermined time, information indicating the emotions that the user U was feeling at each point in time, information regarding the extent to which the user U was concentrating on the target content C, and information indicating which part of the target content C the user U was paying attention to, and the like.

By referencing the target content C in combination with the time-series information, the information processing device 10 is able to identify the details of the operation performed by the user U at the time a certain image was displayed, as well as the situation of the user U at that time, such as the facial expressions, posture, and emotions of the user U.

The model output data acquisition unit 23 uses a machine learning model M prepared in advance to acquire model output data D related to the details of the screen data sequentially acquired by the screen data acquisition unit 22. The machine learning model M is a machine learning model obtained by learning a relationship between the screen data and descriptive information used to linguistically describe the details of the screen data.

The machine learning model M used in the present implementation may be a model based on various techniques as long as the model is capable of acquiring information used to linguistically describe the details of the elements constituting the target content C. For example, when the analysis target is image data showing a horse with a man riding on it, it is desirable that the machine learning model M not simply output the names and positions of the objects (horse, man, and the like) contained in the image, but rather be a model capable of ultimately obtaining a descriptive sentence such as, “A samurai is riding a horse through the wilderness”. The machine learning model M capable of producing such an output may be generated by a technique such as CLIP (Contrastive Language-Image Pre-training).

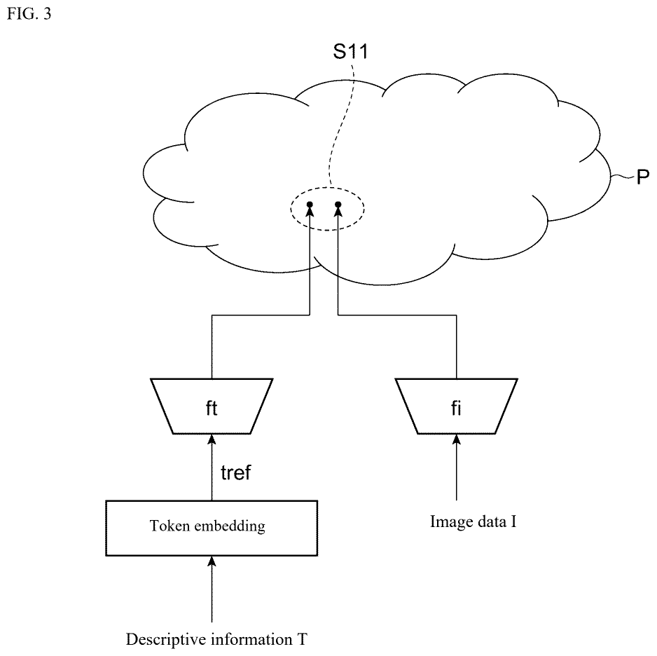

However, in the present implementation, the model output data D acquired by the model output data acquisition unit 23 as output from the machine learning model M need not be a descriptive sentence that can be understood by humans, and may only be information that corresponds to linguistic information. Hereinafter, one example of a learning process for generating the machine learning model M used by the information processing device 10 according to the present implementation will be described using FIG. 3. Note that, although a case in which the screen data is two-dimensional image data will be described here, similar learning may be performed to generate the machine learning model M even when the screen data is rendering data for rendering a spatial image showing the state of a virtual three-dimensional space.

A learning processing device for executing the learning process in the present example receives a plurality of sets of learning data, each set consisting of image data and descriptive information that linguistically describes the image data. For each set of learning data, the learning device divides the descriptive information contained in the set into tokens (for example, words) t and obtains an embedding tref thereof (token embedding). The learning processing device then generates description-related data ft (tref) by encoding the tokens using a text encoder. The description-related data ft (tref) is multi-dimensional vector data, and corresponds to one piece of coordinate information in the abstract space.

The learning processing device also generates image-related data fi (I) obtained by inputting image data I included in the same set as the descriptive information T to an image encoder. The learning processing device sets the image encoder so that the image-related data fi (I) also becomes vector data of the same dimension as the description-related data ft (tref). The image-related data fi (I) also corresponds to one piece of coordinate information in the abstract space.

The learning processing device performs machine learning on each encoder ft and fi so that the description-related data ft (tref) and the image-related data fi (I) are placed close to each other within the above-mentioned predetermined abstract space (a space in the vector dimension of the description-related data and the image-related data, known as the multimodal embedding space in CLIP). As a result, conceptually, as illustrated in the example of FIG. 3, the image data and the descriptive information describing such are associated with each other within a predetermined abstract space P (S11). Note that in the above example, the text encoder ft may use a well-known transformer network, and the image encoder fi may use a Vision Transformer (ViT).

In the present implementation, data of the machine learning model M generated by such machine learning is stored in advance in the storage unit 12. The model output data acquisition unit 23 inputs data of a frame image constituting the target content C acquired by the screen data acquisition unit 22 to the machine learning model M and outputs the output as the model output data D.

When using the machine learning model M that converts each element into a vector within the above-mentioned abstract space P, the model output data D may be the image-related data fi (I) itself obtained by inputting frame image data I constituting the target content C into the image encoder fi. The model output data D may also be data related to a character string representation obtained by inputting the image-related data fi (I) into a decoder that performs the reverse conversion of the text encoder that converts tokens corresponding to the descriptive information T into a vector representation. Such model output data D is data that more directly represents words and written expressions related to the frame image data I.

Furthermore, an index value (such as cosine similarity) indicating the distance within the abstract space P between the description-related data ft (tref) corresponding to the pre-prepared descriptive information T and the image-related data fi (I) may be calculated, and the evaluation results using this index value may be used as the model output data D. By using such index values, it is possible to evaluate the extent to which the frame image data I corresponds to the details expressed by the predetermined descriptive information T. For example, by preparing a plurality of pieces of descriptive information T related to violent expressions in advance and evaluating how close the frame image data I to be analyzed is to the plurality of pieces of descriptive information T within the abstract space P, it is possible to determine whether the frame image data I contains violent expressions.

Furthermore, the model output data D may be data obtained by performing clustering on the distribution in the abstract space P obtained by converting a plurality of pieces of image data into vector representations. For example, a plurality of pieces of image data extracted under predetermined conditions are input to the image encoder fi, and the obtained plurality of pieces of image-related data fi (I) are subjected to clustering processing to group such within the abstract space P. As a result, when three clusters are extracted, for example, it can be inferred that the image data belonging to each of these clusters are images having similar meanings. Furthermore, the descriptive information T corresponding to the position of each cluster may be acquired as the model output data D. These pieces of descriptive information T may be used to roughly describe the details of the image data belonging to the corresponding cluster.

In any case, the model output data D obtained by inputting certain image data into the machine learning model M is data that may be used to represent the details of the image data in a manner that can be understood by humans. The guidance presentation unit 24, which will be described later, uses the model output data D to present guidance regarding the details of the target content C.

Note that the machine learning model M described above is merely an example, and in the present implementation, the model output data acquisition unit 23 may use various models capable of obtaining the meaning of an image or descriptive information about the image as the machine learning model M. For example, the model output data acquisition unit 23 may use as the machine learning model M a model that has been trained to obtain answers to questions about images by learning images, questions about the images, and the answers thereof. Furthermore, by inputting sentences or the like that condition the viewpoint of information extraction along with the image, a model that has been trained to be able to extract information about a specific viewpoint may be used as the machine learning model M. By using such a machine learning model, the guidance presentation unit 24, which will be described later, is capable of presenting guidance information that focuses on a specific viewpoint.

The guidance presentation unit 24 determines the details that should be given as guidance to the user U based on the model output data D acquired by the model output data acquisition unit 23, and executes guidance processing to present the determined details to the user U as guidance information. By determining the guidance information using the model output data D, the guidance presentation unit 24 can be expected to provide guidance having details that are appropriate for the content being presented to the user U at that time and the situation of the user U, even when thorough rules and the like for determining guidance information have not been defined in advance.

Specifically, for example, the guidance presentation unit 24 presents to the user U, as a message, a character string such as advice for the user U or a supplementary explanation regarding the details of the current content. This message may be displayed as a message image superimposed or the like on the screen displayed by the content output unit 21, or may be played back as message audio. The guidance presentation unit 24 may also present guidance to the user U by displaying on a screen, such as a display pointing to a specific position on the screen displayed by the content output unit 21.

Below, several specific examples of the processing in which the guidance presentation unit 24 presents guidance to the user U will be described.

As a first example, an example in which a conversation with the user U regarding the details of the screen will be described. In the present example, the guidance presentation unit 24 functions as a virtual agent capable of communicating with the user U.

In the present example, the guidance presentation unit 24 determines the details of conversational text to be presented to the user U at a predetermined timing, such as when a certain amount of time has passed, when a scene presented on the screen changes, or when audio spoken by the user U is recognized, and displays the determined conversational text details on the screen as a message image or plays such back as message audio.

Specifically, the guidance presentation unit 24 determines the details of the conversational text to be presented using model output data D acquired based on screen data presented to the user U within a predetermined period of time in the recent past. By determining the details of the conversational text using the model output data D in this manner, the guidance presentation unit 24 is able to present to the user U conversational text related to the details most recently displayed on the screen, the most recent actions of the character operated by the user U, and the like.

At this time, it is desirable that the guidance presentation unit 24 not simply descriptively describe the details and the like recognized from the screen data, but present a message including impressions and emotional cognition regarding the details as conversational text. For example, the guidance presentation unit 24 is able to acquire such a message by inputting the model output data D acquired based on the screen data into a second machine learning model M2. The second machine learning model M2 in the present example is a model that has been machine-trained to generate conversational text, and may be realized using techniques such as well-known generative AI.

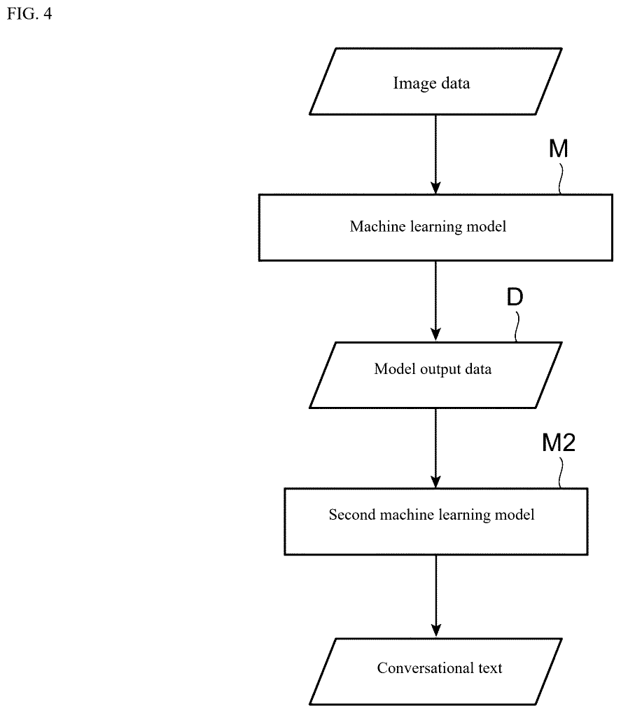

FIG. 4 is a diagram conceptually illustrating the processing of the guidance presentation unit 24 for generating such conversational text. In the example shown in this figure, the model output data D obtained as the output of the machine learning model M is further input into the second machine learning model M2, thereby generating conversational text containing emotional cognition regarding the details of the screen data. According to this method, the guidance presentation unit 24 is able to present conversational text such as, for example, “The item has fallen under the tree”, “Everyone is drinking and singing and looks like they're having fun”, or “That was close. I was surprised by the sudden attack from the roof”, to the user U, as if a human being with emotions were watching the same content as the user U. This allows the user U to view the content while enjoying a conversation with the virtual agent.

In addition, the guidance presentation unit 24 may determine the guidance information to be presented to the user U by performing predetermined processing on the model output data D of the machine learning model M without using the second machine learning model M2. As a specific example, as described above, when using the type of model that outputs descriptive information describing screen data from a specific perspective (such as an answer to a specific question) as the machine learning model M, one that has been trained to generate answers to anticipated user questions may be prepared in advance. In this case, when an anticipated question is received from the user, the guidance presentation unit 24 may present the details of the model output data D obtained using the machine learning model M, or a message or the like containing the details, to the user as guidance information.

Furthermore, the machine learning model M may be configured to output the model output data D in the form of a sentence spoken to the user, or the like, according to details specified in advance. This allows the user to receive, as guidance information, a message that sounds as if it is being spoken by an agent having a conversation with the user.

As a second example, an example will be described in which advice regarding the details of gameplay is presented as guidance information while the user U is playing the game.

In the present example, the guidance presentation unit 24 first determines whether the user U is in a situation in which he or she needs advice based on given conditions. Specifically, for example, the guidance presentation unit 24 infers that the user U needs advice when the user U is repeating the same operation or when it is inferred that the game is not progressing and the same scene is continuing.

As a more specific example, the guidance presentation unit 24 may refer to time-series operation information indicating the details of operational input by the user U, and present advice when it is determined that the user U is repeating the same operation. In addition, the guidance presentation unit 24 may refer to the model output data D that is acquired periodically, and present advice when it is determined from the details of the data that the same scene is being repeated or that no change in the scene has occurred for a predetermined period of time or more. In addition, when it is possible to infer the emotions of the user U based on time-series information obtained by capturing facial expressions of the user U using a camera, or the like, advice may be presented when it is inferred that the user U is irritated.

When a determination is made to present advice, the guidance presentation unit 24 infers the situation in which the user U is placed by referring to the model output data D, and determines the advice according to the situation. For example, when there is a sign at a fork in the road on the screen presented to the user U, advice such as, “Have a look at the sign there” may be presented. Furthermore, when taking damage despite defending against an enemy's fire attack, advice such as, “You need to avoid the fire” may be presented. Note that in this second example, as in the first example, the details of the advice may be realized by a second machine learning model M2 that determines the details of the advice using the model output data D.

In this manner, the guidance presentation unit 24 uses the model output data D acquired from the screen data being presented to the user U in real time to recognize the meaning of the screen being presented to the user U, and determines the details of the advice according to these details. This allows the user U to be provided naturally detailed and specific advice that is in line with the details on the screen, even when the user U does not have a prior understanding of the game details.

As a third example, an example of supporting communication between a plurality of users will be described. In the present example, it is assumed that a plurality of users communicate with each other while sharing a single piece of content, such as when participating in a multiplayer game. Here, a plurality of users sharing a single piece of content means a situation in which the users are presented with a mutually related screen, such as when a plurality of users are viewing the same screen or when each user is operating a character placed in the same virtual space.

In such cases, users may communicate with other users by transmitting short fixed phrases, gestures known as emotes, emoticons, stamps, and the like. Hereinafter, the various actions that users transmit to other users for the purpose of communication will be collectively referred to as messages. Furthermore, among these messages, a message that the user U is able to select and transmit from a plurality of candidates prepared in advance by a program that outputs the target content C will be referred to as a template message. Such template messages have an advantage in that they are easy to input and may be sent easily, but they are limited to pre-prepared types and may lack expressiveness. Therefore, when the user U performs an operation to transmit a template message to another user, the guidance presentation unit 24 generates a message with details that are appropriate to the situation based on the model output data D, and may transmit this generated message as a supplement to the template message instructed by the user U, or may transmit the generated message as a substitute for the template message specified by the user U.

As a specific example, when the user U instructs that another user who defeated an enemy that was attacking him be transmitted a template message such as “Thank you”, the guidance presentation unit 24 may generate a message such as “Wow, you saved me!”, and transmit such to the user specified as the addressee. Alternatively, when the character operated by the user U transmits a template message saying “Here” immediately after placing an item that he or she is holding on the ground, the guidance presentation unit 24 may generate and transmit a message saying “This is for you”.

To achieve such processing, the guidance presentation unit 24 may use another machine learning model M3 that receives model output data D and template messages able to be selected by the user U as input. In the present example, the machine learning model M3 is a model trained by machine learning to accept as input the model output data D, which is the output of the machine learning model M, and a template message, and to generate and output a message that can be used in the situation indicated by the model output data D as an alternative or supplement to the template message.

Furthermore, in the present example, a plurality of machine learning models M3 may be prepared. In this case, the guidance presentation unit 24 selects the machine learning model M3 to use depending on the user to whom the message is to be transmitted, inputs the message specified by the user U and the model output data D into that model, and generates the message to be transmitted to the recipient user. In this case, the plurality of machine learning models M3 may be models generated by learning messages and the like exchanged in the respective different countries or regions, for example. For example, certain gestures may be interpreted differently in different countries, and the like, and the meaning of messages and the situations in which they are used may differ depending on the culture and customs of each country or region. Therefore, a plurality of machine learning models M3 are prepared, which are obtained by performing machine learning on responses between users in each region, and when the user U instructs that a message be transmitted, the guidance presentation unit 24 refers to the attribute information of the user designated as the recipient of the message and selects the machine learning model M3 corresponding to the region to which the user belongs. Then, the specified template message and the model output data D are input to the selected machine learning model M3 to generate a message to be transmitted In this manner, the user U transmitting the message is able to absorb cultural differences and the like and transmit a message having details that are appropriate to the recipient's country or region without being particularly conscious of such. In this case, the plurality of machine learning models M3 need not be generated independently from one another, but may be generated by performing fine tuning or the like on a single machine learning model to additionally learn details related to each region.

Note that, similarly to the first example described above, the guidance presentation unit 24 may use the model output data D of the machine learning model M as-is to present guidance information instead of using another machine learning model M3. In this case, a machine learning model M is used that has previously learned the association between screen data and messages corresponding to the situation of the scene represented by the screen data. Furthermore, rather than preparing a plurality of independent machine learning models for each country or region, messages may be generated using a single machine learning model M or machine learning model M3 that has been pre-trained to enable output tailored to a plurality of countries or regions. In this case, the guidance presentation unit 24 provides attribute information of the recipient user to the machine learning model to be used in advance so as to perform output tailored to the recipient user of the target message, and transmits the output message to the recipient user according to the attribute information. Thus, messages matching the attributes of the recipient may be presented without having to prepare a plurality of machine learning models.

Furthermore, the guidance presentation unit 24 may not only transmit a supplemental message or an alternative message in response to a message transmission instruction from the user U, but may also display guidance that supplements the details of the messages being transmitted and received between users. For example, when the user U transmits a message to another user containing a directive such as, “Let's go to that mountain hut”, the guidance presentation unit 24 uses the model output data D to identify the subject indicated by the directive contained in the screen data. Then, along with the message of the user U, information identifying the object in the virtual space that is the subject of the message (here, the mountain hut) is transmitted to the terminals used by the other users. The user terminal that receives the message displays the specified object (here, the mountain hut) in a manner that highlights the object, such as by placing a pin on the object. This allows other users who have received a message from the user U to easily understand the intent of the message, allowing for smooth communication.

Furthermore, instead of or in addition to highlighting the object, the guidance presentation unit 24 may generate a message or the like describing the position of the object and present such to other users as guidance information. The message may include sentences that describe the location coordinates, direction, distance, and the like, of the subject.

In the present example, when the screen data acquired by the screen data acquisition unit 21 is not a frame image presented to the user U, but rendering data containing information about an object in the virtual space, it is desirable that the guidance presentation unit 24 identify the object itself specified by the user U based on the correspondence between the model output data D and the rendering data. This makes it easy to transmit and share information about the identified object to terminals used by other users.

As described above, according to the information processing device 10 of the present implementation, by utilizing the model output data D acquired from the screen data presented to the user U, it is possible to present the user U with guidance and responses having details that are appropriate to the situation of the user U at that time.

The implementations of the present specification are not limited to those described above. For example, in the above description, the machine learning model M takes screen data as input and outputs model output data D, but the machine learning model M may also accept as input not only screen data, but also various other data related to the target content C, such as audio data and time-series information such as the details of operations received from the user.

Furthermore, instead of using the entirety of the screen data as input, the model output data acquisition unit 23 may input a portion of the extracted screen data based on a predetermined condition to the machine learning model M to acquire the model output data D. Specifically, for example, the model output data acquisition unit 23 may extract an area determined according to the position of the user character from the frame image presented to the user and input such into the machine learning model M. Furthermore, information about objects contained in an area of the virtual space determined by the position of the user character and/or other objects (for example, characters operated by other users playing the game together) may be extracted and input into the machine learning model M. With this type of control, model output data D related to the details within the area may be acquired, particularly for an area related to the character being operated by the user or an area that is expected to attract the user's attention.

In addition, in the above description, the information processing device 10 according to an implementation of the present specification itself stores the machine learning model M, and the model output data D is acquired by inputting screen data into the machine learning model M, but this is merely one example. The information processing device 10 may acquire the model output data D by using a machine learning model M retained by another computer connected via a communication network, for example.

### Description of Reference Numerals

10 Information processing device, 11 Control unit, 12 Storage unit, 13 Interface unit, 14 Display device, 15 Operation device, 21 Target content output unit, 22 Screen data acquisition unit, 23 Model output data acquisition unit, 24 Guidance presentation unit.

What is claimed is:

1. An information processing device comprising:
one or more computer processors; and
one or more non-transitory computer-readable media that store instructions which, when executed by the one or more computer processors, cause the one or more computer processors to perform operations comprising:
sequentially acquiring, with regard to target content having details that change over time, screen data related to details on a screen of the target content while the target content is being output;
sequentially acquiring model output data corresponding to the screen data related to the details on the screen of the target content using a machine learning model obtained by machine learning a relationship between the screen data and descriptive information that linguistically describes the details of the screen data; and
executing predetermined processing based on the acquired model output data.

2. The information processing device of claim 1, wherein the operations comprise:
acquiring predetermined time-series information while the target content is being output;
generating guidance information for a user viewing the target content based on the acquired time-series information and the acquired model output data; and
presenting the guidance information to the user.

3. The information processing device of claim 1, wherein the operations comprise:
inputting the acquired model output data into a second machine learning model trained to generate conversational text; and
presenting the obtained conversational text to the user viewing the target content.

4. The information processing device of claim 1, wherein the operations comprise:
receiving, from the user viewing the target content, a transmission instruction for transmitting a predetermined template message to another user;
determining details of a message to be transmitted to the other user based on the acquired model output data and the template message specified in the transmission instruction; and
transmitting the determined message to the other user.

5. The information processing device of claim 4, wherein the operations comprise:
inputting the acquired model output data and the template message specified in the transmission instruction to a machine learning model selected according to the other user from among a plurality of machine learning models prepared in advance for message generation; and
determining the details of the message to be transmitted to the other user.

6. The information processing device of claim 1, wherein the screen data includes information that identifies an appearance, position, or orientation of objects placed in a three-dimensional virtual space.

7. The information processing device of claim 1, wherein the target content comprises video game content.

8. One or more non-transitory computer-readable media that store instructions which, when executed by one or more computer processors, cause the one or more computer processors to perform operations comprising:
sequentially acquiring, with regard to target content having details that change over time, screen data related to details on a screen of the target content while the target content is being output;
sequentially acquiring model output data corresponding to the screen data related to the details on the screen of the target content using a machine learning model obtained by machine learning a relationship between the screen data and descriptive information that linguistically describes the details of the screen data; and
executing predetermined processing based on the acquired model output data.

9. The media of claim 8, wherein the operations comprise:
acquiring predetermined time-series information while the target content is being output;
generating guidance information for a user viewing the target content based on the acquired time-series information and the acquired model output data; and
presenting the guidance information to the user.

10. The media of claim 8, wherein the operations comprise:
inputting the acquired model output data into a second machine learning model trained to generate conversational text; and
presenting the obtained conversational text to the user viewing the target content.

11. The media of claim 8, wherein the operations comprise:
receiving, from the user viewing the target content, a transmission instruction for transmitting a predetermined template message to another user;
determining details of a message to be transmitted to the other user based on the acquired model output data and the template message specified in the transmission instruction; and
transmitting the determined message to the other user.

12. The media of claim 11, wherein the operations comprise:
inputting the acquired model output data and the template message specified in the transmission instruction to a machine learning model selected according to the other user from among a plurality of machine learning models prepared in advance for message generation; and
determining the details of the message to be transmitted to the other user.

13. The media of claim 8, wherein the screen data includes information that identifies an appearance, position, or orientation of objects placed in a three-dimensional virtual space.

14. The media of claim 8, wherein the target content comprises video game content.

15. A computer-implemented method comprising:
sequentially acquiring, with regard to target content having details that change over time, screen data related to details on a screen of the target content while the target content is being output;
sequentially acquiring model output data corresponding to the screen data related to the details on the screen of the target content using a machine learning model obtained by machine learning a relationship between the screen data and descriptive information that linguistically describes the details of the screen data; and
executing predetermined processing based on the acquired model output data.

16. The method of claim 15, comprising:
acquiring predetermined time-series information while the target content is being output;
generating guidance information for a user viewing the target content based on the acquired time-series information and the acquired model output data; and
presenting the guidance information to the user.

17. The method of claim 15, comprising:
inputting the acquired model output data into a second machine learning model trained to generate conversational text; and
presenting the obtained conversational text to the user viewing the target content.

18. The method of claim 15, comprising:
receiving, from the user viewing the target content, a transmission instruction for transmitting a predetermined template message to another user;
determining details of a message to be transmitted to the other user based on the acquired model output data and the template message specified in the transmission instruction; and
transmitting the determined message to the other user.

19. The method of claim 18, comprising:
inputting the acquired model output data and the template message specified in the transmission instruction to a machine learning model selected according to the other user from among a plurality of machine learning models prepared in advance for message generation; and
determining the details of the message to be transmitted to the other user.

20. The method of claim 15, wherein the screen data includes information that identifies an appearance, position, or orientation of objects placed in a three-dimensional virtual space.
